(19) United States
(12) Patent Application Publication
(10) Pub. No.: US 2021/0287953 A1
(43) Pub. Date: Sep. 16, 2021

(54) EMBEDDED MOLDING FAN-OUT (EMFO) PACKAGING AND METHOD OF MANUFACTURING THEREOF

(71) Applicant: DiDrew Technology (BVI) Limited, Tortola (VG)

(72) Inventors: Minghao Shen, Tortola (VG); Xiaotian Zhou, Tortola (VG)

(21) Appl. No.: 16/817,388

(22) Filed: Mar. 12, 2020

(51) Int. Cl. H01L 23/31; H01L 23/498; H01L 23/00

(52) U.S. Cl. CPC H01L 23/3121; H01L 2224/02379; H01L 24/07; H01L 23/49811

(57) ABSTRACT

Embedded molding fan-out (eMFO) packaging technology has the benefit of delivering six-sided protection of a semiconductor device to reduce delamination failures and provide better reliability and performance. Additionally, semiconductor devices utilizing eMFO packaging technology need not worry about dielectric transition planarity issues, or having to use expensive copper posts or pillars or an extra dielectric layer. In short, implementation of eMFO packaging technology means lower manufacturing cost and better overall performance.

### FIELD OF THE INVENTION

The present disclosure relates to semiconductor packaging technologies.

### BACKGROUND

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The atomic structure of semiconductor material allows its electrical conductivity to be manipulated by the application of an electric field or base current or through the process of doping. Doping introduces impurities into the semiconductor material to manipulate and control the conductivity of the semiconductor device.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each semiconductor die is typically identical and contains circuits formed by electrically connecting active and passive components. Back-end manufacturing involves singulating individual semiconductor die from the finished wafer and packaging the die to provide structural support and environmental isolation.

FIG. 1A shows schematic, cross-sectional view of a typical semiconductor package 100. In this instance, a semiconductor device 110 can be encapsulated with an encapsulation material 120. A redistribution layer (RDL) 130 with multiple dielectric layers 140A, 140B and a solder ball 150 can be formed thereon. In this instance, a metal post or pillar 160, such as copper, can be formed on an active region of the semiconductor device 110 to connect the RDL 130 of the package 100 to the underlying silicon die circuitry 110.

In operation, the copper post 160 can be formed after the encapsulating step, using a grinding process to expose the upper surface of the copper post 160 for subsequent electrical connectivity to the RDL. Unfortunately, the grinding process can often smear the surface of the copper post 160 as best illustrated in FIG. 1B, which is a top view illustration of copper smearing 180 and other artifacts that can be seen when manufacturing the semiconductor package 100 of FIG. 1A. Copper smearing 180 can cause metal copper to diffuse to other parts of the encapsulation material 120 thereby causing electrical shorts or creating other circuitry problems. Additionally, copper smearing 180 may also create topography issues and make subsequent semiconductor processing steps difficult and challenging.

Accordingly, there exists a need in the industry for improved packaging processes that can reduce cost and manufacturing time compared to such prior processes.

### BRIEF SUMMARY

Disclosed are embedded molding fan-out (eMFO) packaging technologies having the benefit of delivering six-sided protection of a semiconductor device with reduced delamination failures and provide better reliability and performance.

In one embodiment, an eMFO packaging system includes a semiconductor substrate having a semiconductor device with an active region and a sacrificial structure formed on the active region. The system includes a carrier substrate having an adhesive layer, where the semiconductor substrate is disposed on the carrier substrate with the semiconductor substrate in contact with the adhesive layer. An encapsulation material can be used to at least partially encapsulate the semiconductor substrate and a portion of the active region, whereby an upper surface of the encapsulation material is coplanar with an upper surface of the sacrificial structure. The system further includes a redistribution layer (RDL) structure formed over the upper surface of the encapsulation material, after removal of the sacrificial structure, where at least a portion of the RDL structure is in electrical contact with the active region of the semiconductor device, the RDL structure without a non-conformal metal structure.

In one embodiment, the semiconductor substrate can be removed from the carrier substrate to form the semiconductor device. In another embodiment, an insulating layer may encapsulate the semiconductor substrate and at least a portion of the encapsulation material, whereby the insulating layer is coplanar with the semiconductor substrate and a lower surface of the encapsulation material.

In one embodiment, the sacrificial structure is formed from at least one of photo-sensitive polymers, non-photo-sensitive polymers, positive photoresists, negative photoresists, photo-imageable dielectric (PID) material, non-photo-imageable dielectric materials, benzocyclobutene (BCB), polybenzoxazoles (PBO), polyimide (PI), and heat-resistant thermoplastics. In another embodiment, the RDL structure of the system includes only a single dielectric layer. In yet another embodiment, the non-conformal metal structure includes a fill-up metal post or pillar.

In one embodiment, a method of forming an eMFO package includes the steps of: (a) providing a semiconductor substrate having a semiconductor device with an active region and a sacrificial structure formed on the active region, (b) providing a carrier substrate having an adhesive layer, (c) mounting the semiconductor substrate over the carrier substrate, whereby the semiconductor substrate is in contact with the adhesive layer, (d) encapsulating at least a portion of the semiconductor substrate and the sacrificial structure with an encapsulation material, whereby an upper surface of the encapsulation material is coplanar with an upper surface of the sacrificial structure, (e) removing the sacrificial structure exposing the active region of the semiconductor device, and (f) forming a redistribution layer (RDL) structure over the semiconductor device, whereby at least a portion of the RDL structure is in electrical contact with the active region of the semiconductor device.

In one embodiment, the method further includes: (g) removing the semiconductor substrate from the carrier substrate to form the semiconductor device. In yet another embodiment, the method further includes: (h) encapsulating the semiconductor substrate and at least a portion of the encapsulation material with an insulating layer, whereby the insulating layer is coplanar with the semiconductor substrate and a lower surface of the encapsulation material.

In one embodiment, the providing step (a) includes forming the sacrificial structure from at least one of photo-sensitive polymers, non-photo-sensitive polymers, positive photoresists, negative photoresists, photo-imageable dielectric (PID) material, non-photo-imageable dielectric materials, benzocyclobutene (BCB), polybenzoxazoles (PBO), polyimide (PI), and heat-resistant thermoplastics.

In one embodiment, the encapsulating step (d) includes planarizing the upper surface of the encapsulation material to be coplanar with the upper surface of the sacrificial structure via a planarizing process. In one embodiment, the removing step (e) includes removing the sacrificial structure with at least one of dry etch and wet etch processing. In one embodiment, the forming step (f) includes forming the RDL structure without a non-conformal metal structure. In another embodiment, the non-conformal metal structure includes a fill-up metal post or pillar.

In one embodiment, another method of forming an eMFO package includes the steps of: (a) providing a semiconductor substrate having a semiconductor device with an active region and a sacrificial structure formed on the active region, (b) providing a carrier substrate having an adhesive layer, (c) mounting the semiconductor substrate over the carrier substrate, whereby the semiconductor substrate is in contact with the adhesive layer, (d) encapsulating at least a portion of the semiconductor substrate and the sacrificial structure with an encapsulation material, whereby an upper surface of the encapsulation material is coplanar with an upper surface of the sacrificial structure, (e) removing the sacrificial structure exposing the active region of the semiconductor device, (f) forming a redistribution layer (RDL) structure over the semiconductor device, whereby at least a portion of the RDL structure is in electrical contact with the active region of the semiconductor device, (g) removing the semiconductor substrate from the carrier substrate to form the semiconductor device, and (h) encapsulating the semiconductor substrate and at least a portion of the encapsulation material with an insulating layer, whereby the insulating layer is coplanar with the semiconductor substrate and a lower surface of the encapsulation material.

In one embodiment, the providing step (a) includes forming the sacrificial structure from at least one of photo-sensitive polymers, non-photo-sensitive polymers, positive photoresists, negative photoresists, photo-imageable dielectric (PID) material, non-photo-imageable dielectric materials, benzocyclobutene (BCB), polybenzoxazoles (PBO), polyimide (PI), and heat-resistant thermoplastics.

In one embodiment, the encapsulating step (d) includes planarizing the surface of the encapsulation material to be coplanar with the upper surface of the sacrificial structure via a planarizing process. In one embodiment, the removing step (e) includes removing the sacrificial structure with at least one of dry etch and wet etch processing. In one embodiment, the forming step (f) includes forming the RDL structure without a non-conformal metal structure. In another embodiment, the non-conformal metal structure includes a fill-up metal post or pillar.

In one embodiment, a method of manufacturing a semiconductor device includes the following steps: (a) providing a semiconductor substrate having a semiconductor device with an active region and a sacrificial structure formed on the active region; (b) providing a carrier substrate having an adhesive layer; (c) mounting the semiconductor substrate over the carrier substrate, whereby the semiconductor substrate is in contact with the adhesive layer; (d) encapsulating at least a portion of the semiconductor substrate and the sacrificial structure with an encapsulation material, whereby an upper surface of the encapsulation material is coplanar with an upper surface of the sacrificial structure; (e) removing the sacrificial structure exposing the active region of the semiconductor device; (f) forming a dielectric layer over at least a portion of the encapsulation material and the semiconductor device; and (g) forming a redistribution layer (RDL) structure over the semiconductor device, whereby at least a portion of the RDL structure is in electrical contact with the active region of the semiconductor device.

In another embodiment, a method of manufacturing a semiconductor device includes the following steps: (a) providing a semiconductor substrate having a semiconductor device with an active region; (b) providing a carrier substrate having an adhesive layer and a sacrificial structure formed on a portion of the adhesive layer; (c) mounting the semiconductor substrate over the carrier substrate, whereby the active region is in contact with the sacrificial structure; (d) encapsulating at least a portion of the semiconductor substrate and the sacrificial structure with an encapsulation material, whereby the encapsulation material under-fills spacing between the semiconductor substrate and the carrier substrate; (e) removing the semiconductor substrate from the carrier substrate; (f) removing the sacrificial structure exposing the active region of the semiconductor device; and (g) forming a redistribution layer (RDL) structure over the semiconductor device, whereby at least a portion of the RDL structure is in electrical contact with the active region of the semiconductor device.

### BRIEF DESCRIPTION OF THE DRAWINGS

FIG. 1A is a schematic, cross-sectional view of a typical semiconductor package.

FIG. 1B is a top view illustration of copper smearing when manufacturing the semiconductor package of FIG. 1A.

FIGS. 2A-2H show schematic, cross-sectional diagrams of an exemplary method for fabricating an embedded molding fan-out (eMFO) package according to embodiments of the present disclosure.

FIGS. 3A-3J show schematic, cross-sectional diagrams of another exemplary method for fabricating an eMFO package according to embodiments of the present disclosure.

FIGS. 4A-4G show schematic, cross-sectional diagrams of yet another exemplary method for fabricating an eMFO package according to embodiments of the present disclosure.

FIG. 5 is a process flow diagram showing an exemplary method for fabricating an eMFO package according to the present disclosure.

FIG. 6 is a process flow diagram showing another exemplary method for fabricating an eMFO package according to the present disclosure.

FIG. 7 is a process flow diagram showing yet another exemplary method for fabricating an eMFO package according to the present disclosure.

### DETAILED DESCRIPTION

This disclosure relates to a wafer level packaging process. For example, in semiconductor wafer packaging processes, the wafer can be a semiconductor wafer or device wafer which has thousands of chips on it. Thin wafers, especially ultra-thin wafers (thickness less than 60 microns or even 30 microns) are very unstable, and more susceptible to stress than traditional thick wafers. During processing, thin wafers may be easily broken and warped. Therefore, temporary bonding to a rigid support carrier substrate can reduce the risk of damage to the wafer. However, the use of the support carrier involves attaching the carrier substrate and later removing the carrier substrate. These additional steps allow for the desired increased rigidity at the cost of extra time and expense involved in the manufacturing process. Therefore, the methods disclosed herein allow for a wafer level packaging process that does not require the use of a carrier substrate. Instead, a framing member is molded to have one or more cavities for supporting respective dies. The dies, with the support of the framing member, can then be processed with desired semiconductor packaging operations including RDL formation and dicing into individual chips.

In the following detailed description of the invention, reference is made to the accompanying drawings, which form a part hereof, and in which is shown, by way of illustration, specific embodiments in which the invention may be practiced. These embodiments are described in sufficient detail to enable those skilled in the art to practice the invention. Other embodiments may be utilized and structural changes may be made without departing from the scope of the present invention.

The following detailed description is, therefore, not to be taken in a limiting sense, and the scope of the present invention is defined only by the appended claims, along with the full scope of equivalents to which such claims are entitled.

One or more implementations of the present invention will now be described with reference to the attached drawings, wherein like reference numerals are used to refer to like elements throughout, and wherein the illustrated structures are not necessarily drawn to scale.

The terms “die”, “semiconductor chip”, and “semiconductor die” are used interchangeably throughout this specification. The term wafer is used herein include any structure having an exposed surface onto which a layer is deposited according to the present invention, for example, to form the circuit structure.

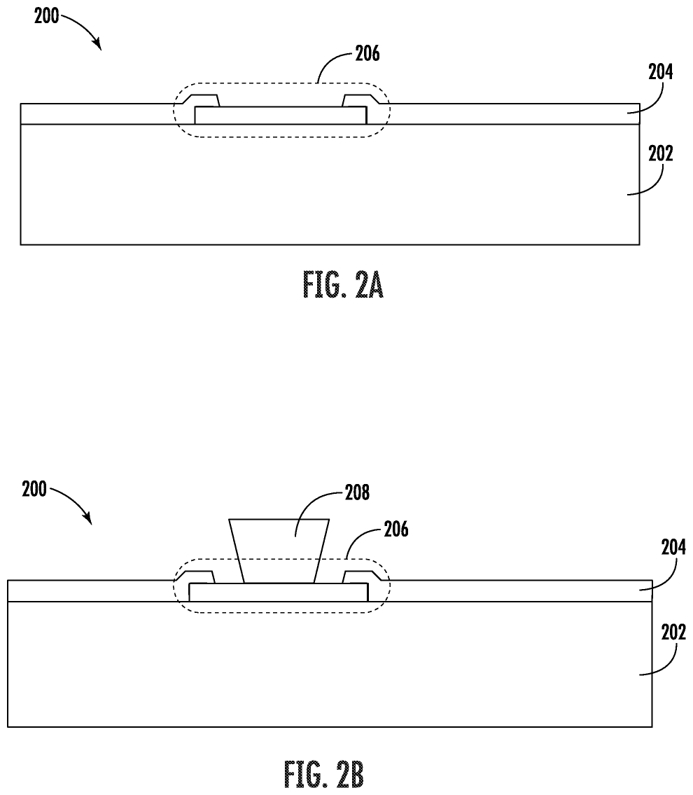

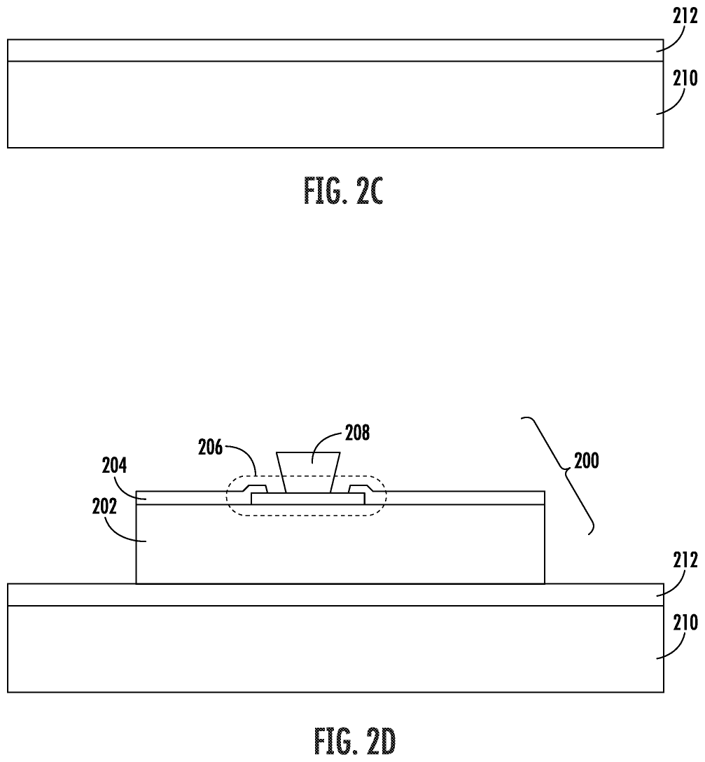

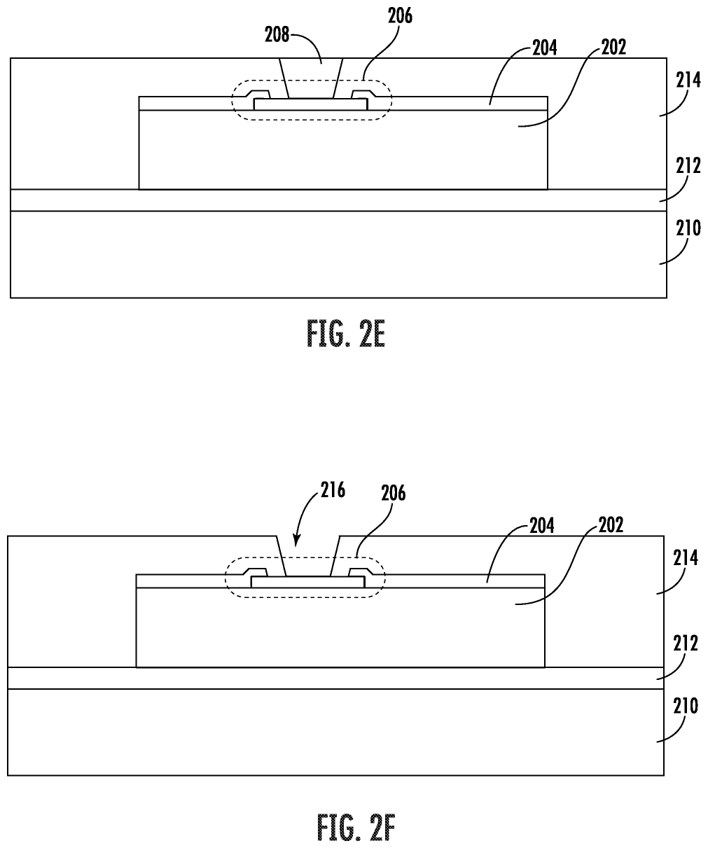

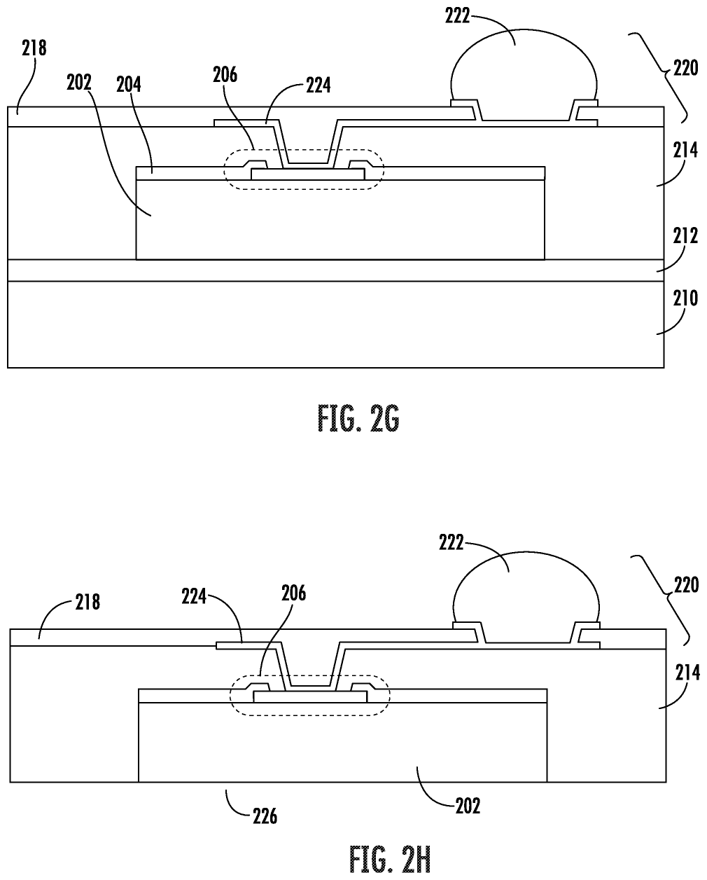

FIGS. 2A-2H show schematic, cross-sectional diagrams of an exemplary method for fabricating an embedded molding fan-out (eMFO) package according to embodiments of the present disclosure.

FIG. 2A is a cross-sectional view of an integrated circuit or semiconductor device 200 formed on a semiconductor substrate 202, which can be made of a semiconductor material such as gallium arsenide (GaAs), gallium nitride (GaN), or silicon (Si), among others. The semiconductor device 200 includes an active region 206 surrounded by a passivation material 204. The passivation material 204 can be formed or deposited over the semiconductor die 200 and selectively over portions of the active region 206. The passivation material 204 can include silicon dioxide, silicon nitride, or other suitable passivation materials for protecting the active region 206 as well as the semiconductor substrate 202. Additionally, portions of the passivation material 204 may be removed (e.g., via wet or dry etch) to expose the active region 106 for subsequent processing.

Next, FIG. 2B shows a cross-sectional view of forming a sacrificial structure 208 on at least a portion of the active region 206. The sacrificial structure 208 may be formed from at least one of photo-sensitive polymers, non-photo-sensitive polymers, positive photoresists, negative photoresists, photo-imageable dielectric (PID) material, non-photo-imageable dielectric materials, benzocyclobutene (BCB), polybenzoxazoles (PBO), polyimide (PI), and heat-resistant thermoplastics, among other suitable materials. In operation, the sacrificial structure 208 may be formed by coating the material onto the semiconductor wafer, patterning at the desired size and location, and removing (e.g., wet chemical developing process or dry etching process) the undesired portions with suitable semiconductor processing techniques as known in the art.

In operation, the sacrificial structure 208 has to be able to sustain structural fidelity during subsequent encapsulation molding compound (EMC) processing steps. In general, EMC molding is carried out from about 130° C. to about 150° C. and EMC curing is carried out from about 150° C. to about 170° C. The sacrificial structure 208, using whatever suitable organic sacrificial material, intended to be a temporary structure, has to be able to sustain its cross-sectional profile or shape structure during these subsequent EMC processing temperatures.

Additionally, although shown as a trapezoid, the sacrificial structure 208 can be formed of other suitable shapes including without limitation square, rectangle, and parallelogram, among others.

FIG. 2C is a cross-sectional view of a carrier substrate 210 having an adhesive layer 212, the adhesive layer 212 being temporary and removable, e.g., a release film. In operation, the adhesive layer 212 may be coated or taped onto the carrier substrate 210. In some embodiments, the adhesive layer 212 may be any temporary bonding and debonding (TBDB) material or other suitable material as can be appreciated by one skilled in the art.

In some embodiments, the adhesive layer 212 may be adhesive tape, or alternatively, may be glue or epoxy applied via a spin-on process, or the like. In other embodiments, the adhesive layer 212 can comprise, for example, die attach film (DAF), which is commercially available. In yet some other embodiments, the adhesive layer 212 can comprise, for example, epoxy paste adhesives that are commercially available for die attachment.

In one embodiment, the carrier substrate 210 can be a metal substrate, for example formed of copper or other desired metal material. The carrier substrate 210 can alternately be a glass, ceramic, sapphire or quartz substrate.

Next, FIG. 2D is a cross-sectional view showing the semiconductor substrate 202 being disposed on the carrier substrate 210 with the semiconductor substrate 202 in direct, physical contact with the adhesive layer 212. In this instance, the semiconductor device 200 is mounted face up on the carrier substrate 210. In operation, this can be carried out by pick and place of the semiconductor substrate 202, after singulation of the dice, face up onto the carrier substrate 210.

FIG. 2E is a cross-sectional view showing planarity of the sacrificial structure 208 and the surrounding encapsulation material 214 after it has been through a planarization process. In this embodiment, an encapsulation material 214 such as an epoxy molding compound (EMC), can be formed or deposited over the semiconductor substrate 202 and the carrier substrate 210 such that the encapsulation material 214 is at least partially encapsulating the semiconductor substrate 202 and a portion of the active region 206.

In operation, the encapsulation material 214 may be formed or deposited followed by a curing step within the temperature ranges as discussed earlier. After the encapsulation material 214 is cured, the encapsulation material 214 becomes partially rigid and forms an encapsulant or encapsulated structure 214. The encapsulation material 214 may have an initial thickness that is greater than desired. In some instances, the encapsulation material 214 may be taller than the sacrificial structure 208 thereby completely covering the sacrificial structure 208. As such, the encapsulation material 214 may need to undergo a planarization process in order to expose the sacrificial structure 208.

In some embodiments, planarization processing may include grinding, chemical mechanical polishing (CMP), laser ablation, or other suitable abrasion processing, with or without wet chemical. The intent of planarization is to make the semiconductor surfaces substantially planar so that subsequent semiconductor processing can be carried out without topographical irregularities. FIG. 2E best illustrates the semiconductor package after a planarization process (e.g., mechanical grinding) has been carried out, whereby an upper surface of the encapsulation material 214 is rendered co-planar with that of an upper surface of the sacrificial structure 208. In other words, the upper surface of the semiconductor package is substantially on the same level or plane, e.g., the upper surfaces of the encapsulation material 214 and the sacrificial structure 208 are substantially on the same axis plane.

Next, FIG. 2F is a cross-sectional view showing removal of the sacrificial structure 208 thereby creating a cavity 216 in its place. Because of the nature of the material used in forming the sacrificial structure 208, the removal can be carried out by known dry etching (e.g., plasma or oxygen ashing, etching, laser ablation) or wet etching (e.g., chemical processing for removing organic polymers) techniques. In this instance, there is reduced concern with smearing of the sacrificial structure 208 when the sacrificial structure 208 is removed and the cavity 216 is created. Furthermore, because of the structural fidelity and the integrity of the material used, upon removal of the sacrificial structure 208 the cavity 216 is able to keep and maintain a suitable cross-sectional profile to allow subsequent semiconductor processing to take place with reduced worry about metal smearing and shorting of circuits.

In one embodiment, removal of the sacrificial structure 208 exposes the active region 206 of the semiconductor device 200 and allows electrical contact to be made. The direct electrical contact can be made by making electrical contacts to the active region 206 through the cavity 216.

FIG. 2G shows a cross-sectional view of a redistribution layer (RDL) structure 220 formed over the upper surface of the encapsulation material 214 after removal of the sacrificial structure 208. As discussed above, at least a portion of the RDL structure 220 is in electrical contact with the active region 206 of the semiconductor device 200. Processing of the RDL structure 220 may also include an under-bump metallization (UBM) process with insulating layers, passivation layers, metal pads, metal pillars, and metal lines, among other suitable layers.

The RDL structure 220 can include various insulating layers and conductive traces in electrical communication with the semiconductor die 200. For example, the RDL structure 220 may include contact formations (e.g., solder balls 222) formed in electrical communication. The RDL structure 220 may also include a conformal metal layer 224 that can be sputtered or electroplated. In one embodiment, the RDL structure 220 may also need only a single photo-imageable dielectric (PID) layer 218.

In some embodiments, formation of the RDL structure 220 may include coating or laminating with a dielectric material (e.g., PID layer 218) to planarize a surface thereof. The remainder of the RDL structure 220 can be formed according to known methods, generally involving formation of layers of metal and dielectric material. The metal structures of the RDL structure 220 may be electrically connected to the dies 200. Also, to provide electrical connection between the RDL structure 220 and other circuitry, a plurality of bumps 222 such as micro-bumps or solder balls may be formed. Optionally, a thermal process may be performed to re-flow the solder bumps 222.

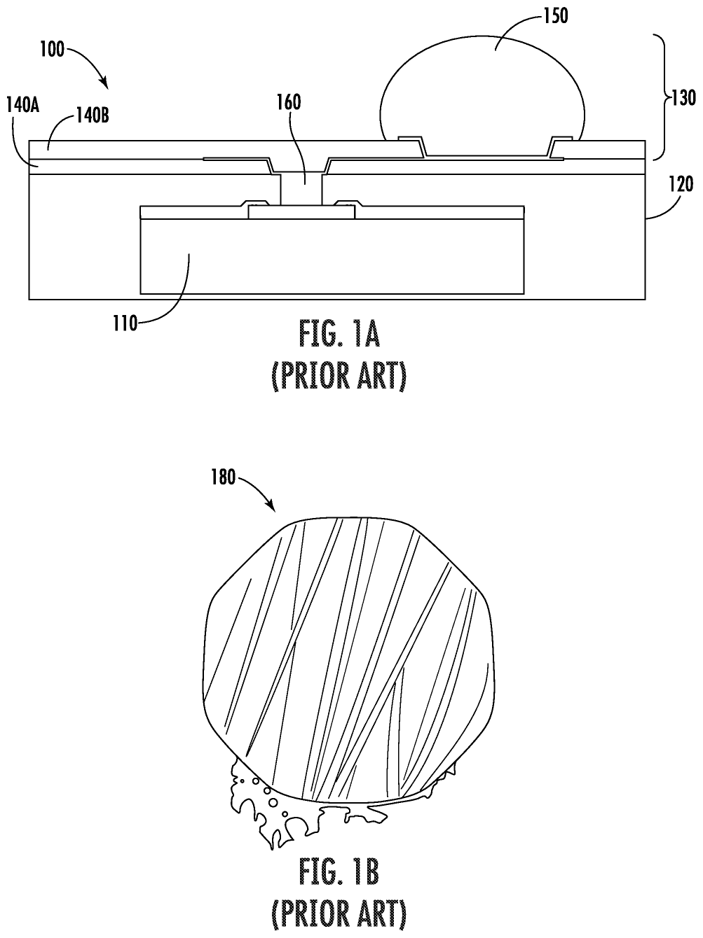

In one embodiment, the RDL structure 220 associated with the current embodiment does not need a non-conformal metal structure 160 similar to that illustrated in FIG. 1A. A non-conformal metal structure includes a fill-up metal post or pillar (e.g., copper post or pillar 160).

Next, FIG. 2H shows the semiconductor substrate 202 being removed from the carrier substrate 210 to form the semiconductor device 200. This can be achieved by removing or de-coupling the semiconductor substrate 202 from the carrier substrate 210 by separating the temporary adhesive layer 212.

In one embodiment, once the carrier substrate 210 and the associated adhesive layer 212 has been decoupled from the semiconductor substrate 202, an insulating layer 226 may be formed on the backside of the semiconductor substrate 202 to provide six-side protection around the entire semiconductor device 200. The insulating layer 226 can be formed of a material similar to that of the encapsulation material 214, whereby the insulating layer 226 encapsulates the semiconductor substrate 202 as well as at least a portion of the encapsulation material 214. In operation, the insulating layer 226 can be formed via a lamination process or other suitable techniques. The insulating layer 226 provides backside lamination protection to the EMC. Once applied, the insulating layer 226 becomes co-planar with the semiconductor substrate 202 as well as a lower surface of the encapsulation material 214.

The disclosed embodiments provide the advantage of not having to form expensive metal posts or pillars 160 within the cavity 216, nor having to worry about smearing or short circuits due to grinding of the copper posts or pillars 160. And because of the material properties of the sacrificial structure 208 and its subsequent removal, there will be little to none smearing during the grinding or other planarization steps, nor will there by shorting concerns thereafter. Additionally, the encapsulation material 214 is able to act as a first-level dielectric thereby eliminating PID layer 140A from the RDL structure 220 thus improving reliability of the RDL structure 220 by removing any additional topography or unevenness issues that may come with PID layer 140A.

Furthermore, due to the flatness or planarity created by the encapsulation material 214, after the sacrificial structure 208 has been removed, the more delicate processing of the RDL structure 220 that follow can be carried out without having to worry about the topography. In short, the currently disclosed structure, utilizing encapsulation material 214 around all six sides of the semiconductor substrate 202, can lead to improved reliability during package drop testing as well as reducing delamination failures associated with low dielectric constant (low-k) materials. Ultimately, the semiconductor device 200 packaged according to the presently disclosed embodiments has the potential of improved package reliability and performance.

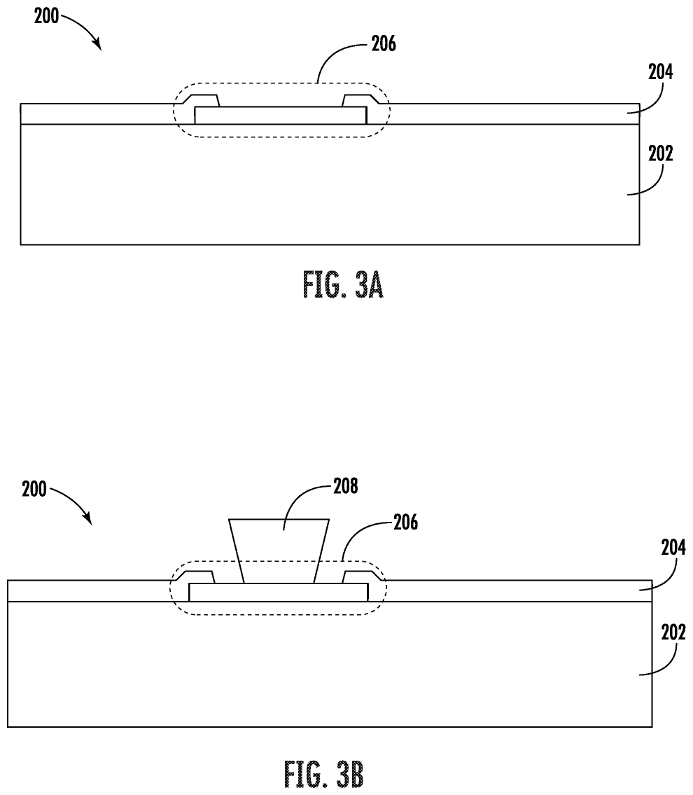

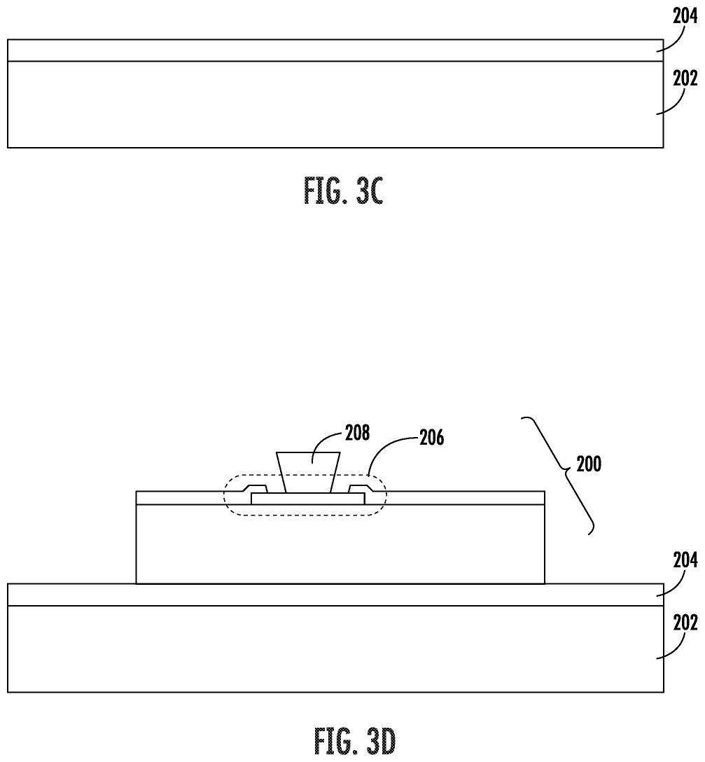

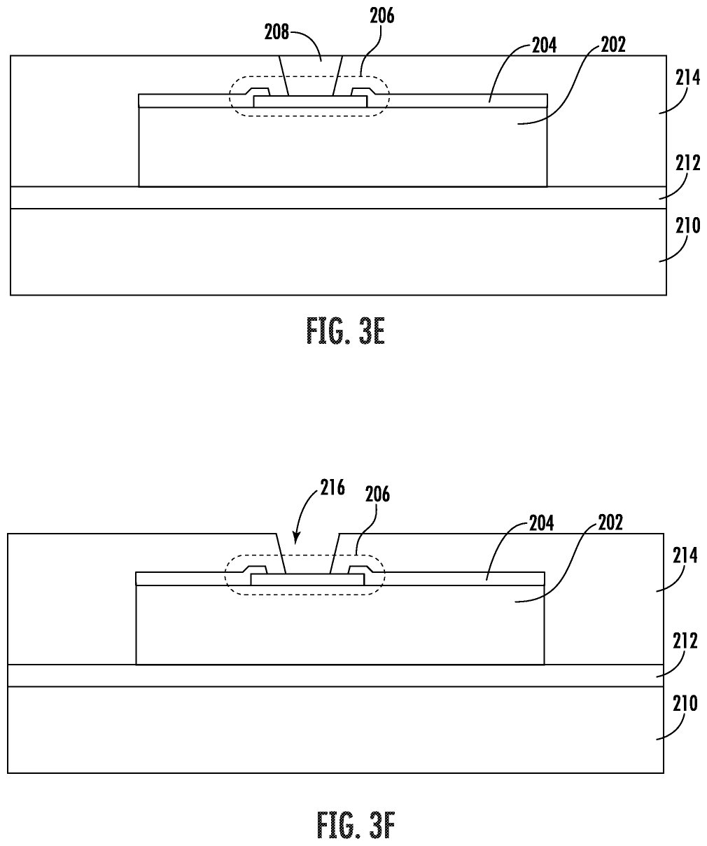

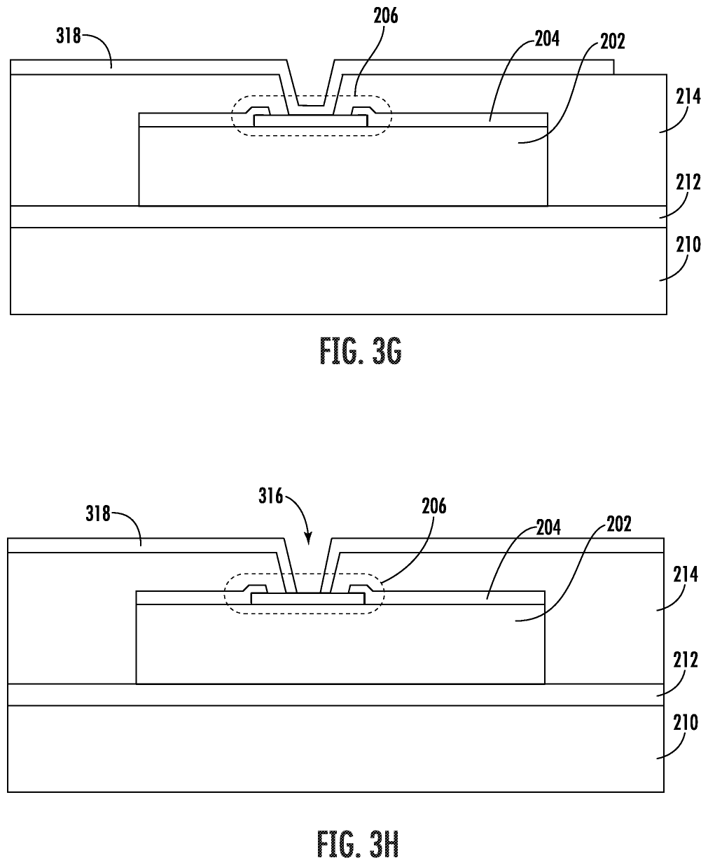

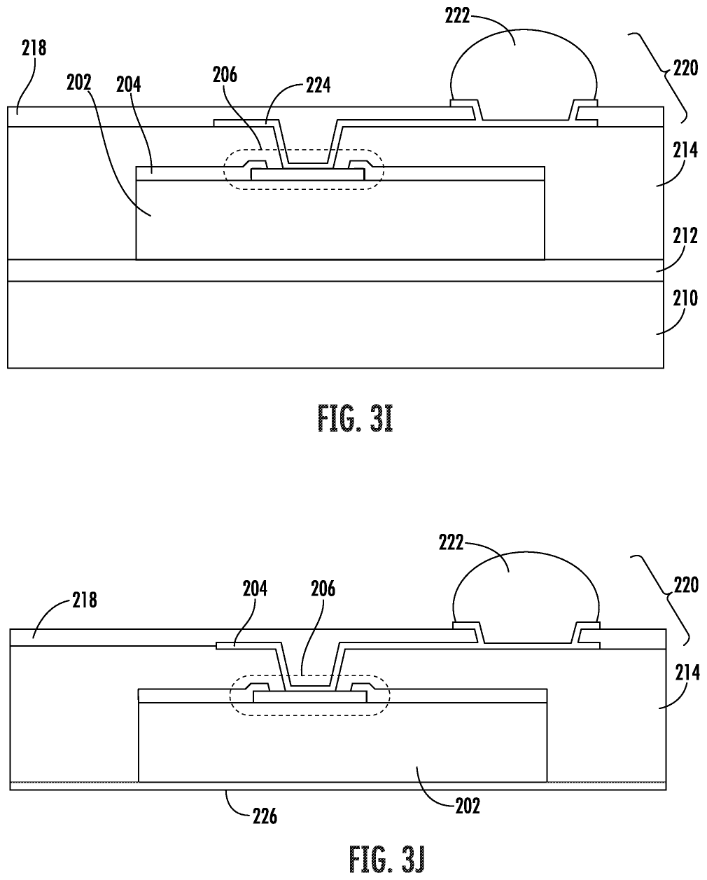

FIGS. 3A-3J show schematic, cross-sectional diagrams of an exemplary method for fabricating an embedded molding fan-out (eMFO) package according to embodiments of the present disclosure.

FIGS. 3A-3F are substantially similar to those of FIGS. 2A-2F above and will not be repeated herein for sake of brevity.

FIG. 3G shows a cross-sectional view of a PID layer 318 being formed over the semiconductor substrate 202. In one embodiment, the PID layer 318 is a dielectric material similar to those discussed above, whereby the PID layer 318 is formed over at least a portion of the encapsulation material 214 and the semiconductor device 200. The PID layer 318 can be formed by coating, sputtering, vapor deposition or other known techniques. Additionally, the PID layer 318 is conformally formed over at least a portion of the encapsulation material 214, the semiconductor substrate 202, the active region 206 of the semiconductor device 200, as well as the carrier substrate 210.

FIG. 3H shows a cross-sectional view of the PID layer 318 whereby a portion has been selectively photo patterned and removed to form a cavity 316 for direct electrical contact with the active region 206 of the semiconductor device 200. The selective lithographic and removal technique of the PID layer 318 can be carried out by known semiconductor processing techniques.

FIG. 3I shows a cross-sectional view of a redistribution layer (RDL) structure 220 formed over the upper surface of the PID layer 318 and within the cavity 316. Similar to FIG. 2G above, at least a portion of the RDL structure 220 is in electrical contact with the active region 206 of the semiconductor device 200. The structure and processing of the RDL structure 220 may be similar to that described above and will not be repeated herein.

In this embodiment, the RDL structure 220 has two PID layers 318, 218 similar to other techniques known in the art. However, the current embodiment still does not utilize a non-conformal metal structure 160 similar to that illustrated in FIG. 1A. A non-conformal metal structure includes a fill-up metal post or pillar (e.g., copper post or pillar 160).

Next, FIG. 3J shows the semiconductor substrate 202 being removed from the carrier substrate 210 to form the semiconductor device 200 similar to that of FIG. 2H, with the exception that the RDL structure 220 now includes two PID layers 318, 218. And like above, an additional insulating layer 226 may be formed on the backside of the semiconductor substrate 202 to provide six-side protection around the entire semiconductor device 200 providing all the benefits of the eMFO package technology as disclosed above.

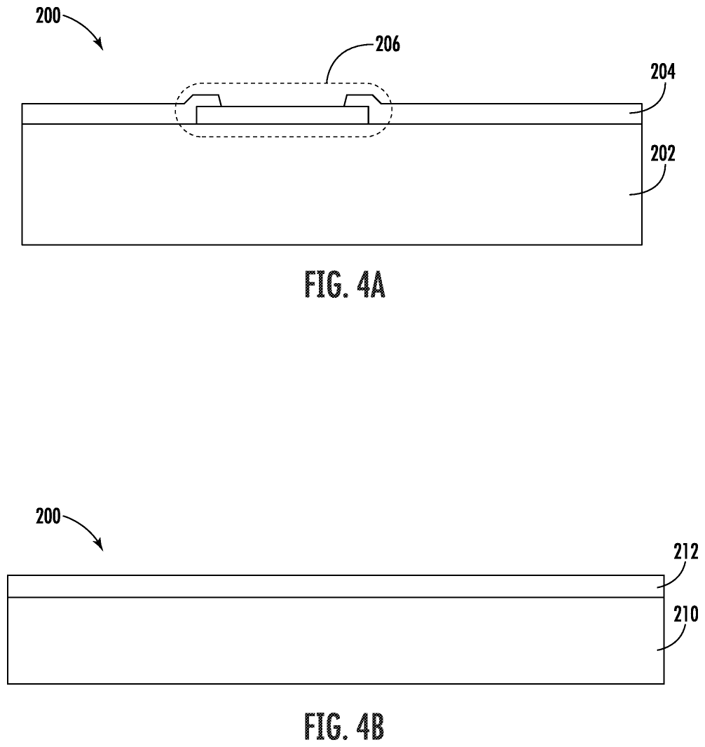

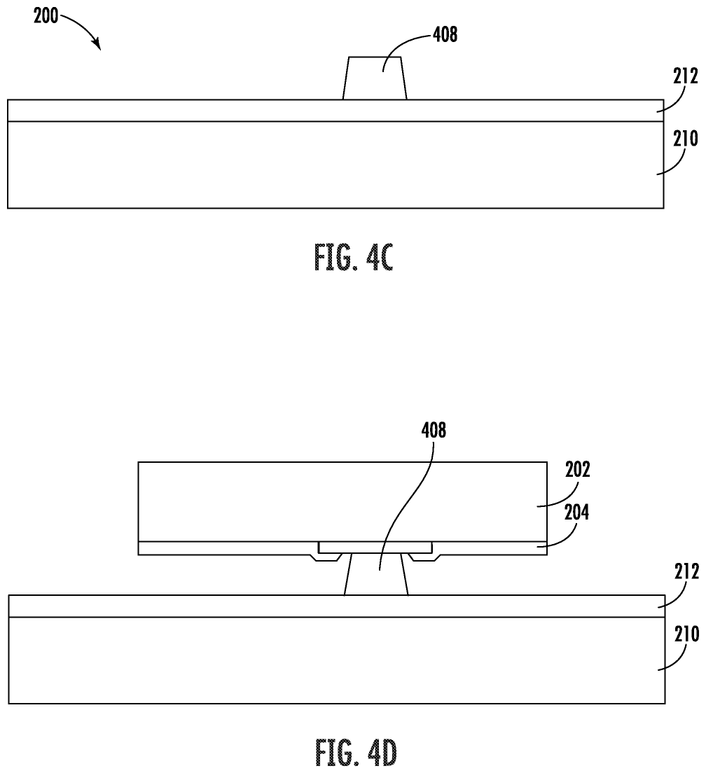

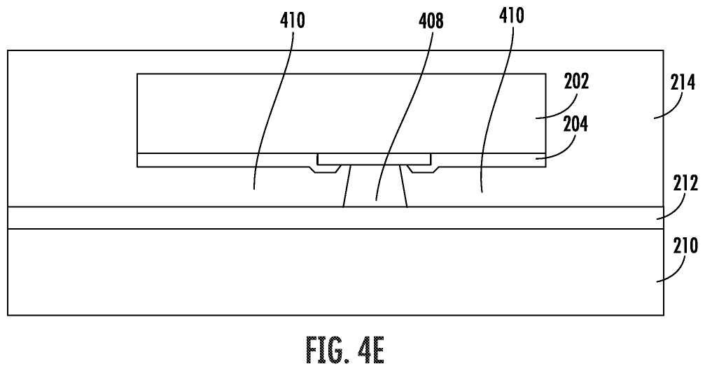

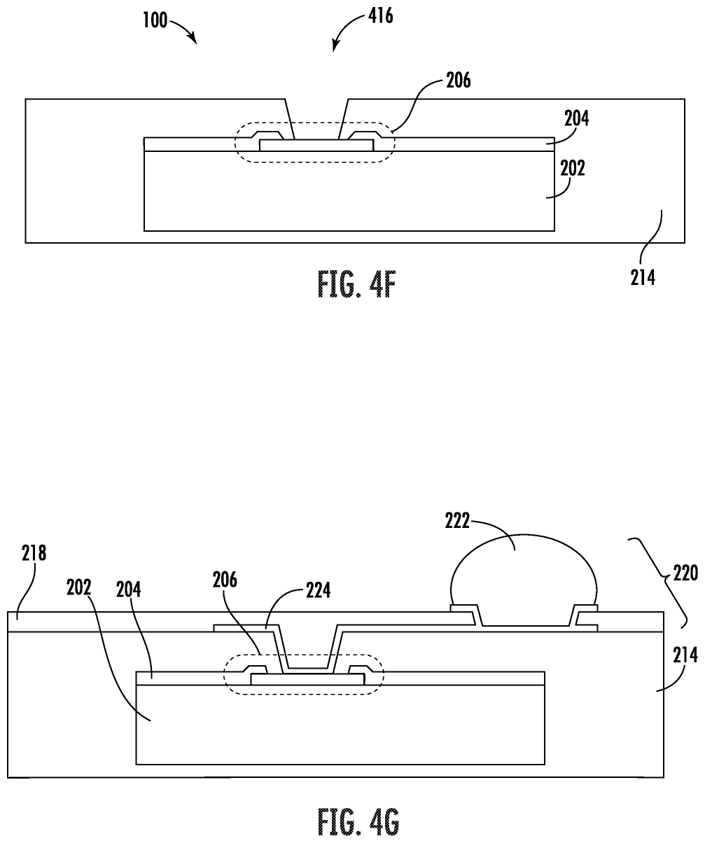

FIGS. 4A-4G show schematic, cross-sectional diagrams of yet another exemplary method for fabricating an eMFO package according to embodiments of the present disclosure.

FIG. 4A is a cross-sectional view of an integrated circuit or semiconductor device 200 formed on a semiconductor substrate 202, which can be made of a semiconductor material such as gallium arsenide (GaAs), gallium nitride (GaN), or silicon (Si), among others. The semiconductor device 200 includes an active region 206 surrounded by a passivation material 204. The passivation material 204 can be formed or deposited over the semiconductor die 200 and selectively over portions of the active region 206. The passivation material 204 can include silicon dioxide, silicon nitride, or other suitable passivation materials for protecting the active region 206 as well as the semiconductor substrate 202. Additionally, portions of the passivation material 204 may be removed (e.g., via wet or dry etch) to expose the active region 106 for subsequent processing.

FIG. 4B is a cross-sectional view of a carrier substrate 210 having an adhesive layer 212, the adhesive layer 212 being temporary and removable, e.g., a release film. In operation, the adhesive layer 212 may be coated or taped onto the carrier substrate 210. In some embodiments, the adhesive layer 212 may be any temporary bonding and debonding (TBDB) material or other suitable material as can be appreciated by one skilled in the art.

In one embodiment, the carrier substrate 210 can be a metal substrate, for example formed of copper or other desired metal material. The carrier substrate 210 can alternately be a glass, ceramic, sapphire or quartz substrate.

Next, FIG. 4C shows a cross-sectional view of forming a sacrificial structure or post 408 on at least a portion of the adhesive layer 212. The sacrificial post 408 may be formed with similar material and technique as those discussed above and will not be elaborated further herein. In this embodiment, the sacrificial post 408 may be formed by initially coating the carrier substrate 210, e.g., adhesive layer 212, with a sacrificial material, patterning the sacrificial material to create the post-like structure, which are designed to later align with die pad passivation openings or active region 206 of the semiconductor device 200. This will become more apparent in subsequent figures and discussion.

FIG. 4D is a cross-sectional view showing the semiconductor substrate 202 being disposed over the carrier substrate 210 with the active region 206 being in direct, physical contact with the sacrificial post 408. In this instance, the semiconductor device 200 is mounted face down on the carrier substrate 210. In operation, this can be carried out by pick and place of the semiconductor substrate 202, after singulation of the dice, face down onto the carrier substrate 210, with appropriate machine alignment. In another embodiment, instead of aligning the active region 206 of the semiconductor device 200 with the sacrificial post 408, die pad passivation openings (not shown) off to the sides of the semiconductor device 200 may instead be aligned with the sacrificial post 408.

FIG. 4E is a cross-sectional view showing encapsulating the semiconductor device 200 with an encapsulation material 214. In this embodiment, an encapsulation material 214 such as an epoxy molding compound (EMC), can be formed or deposited over the semiconductor substrate 202 and the carrier substrate 210 such that the encapsulation material 214 is at least partially encapsulating the semiconductor substrate 202 along with a portion of the active region 206. Additionally, the encapsulation material 214 also encapsulates the sacrificial post 408. Furthermore, the encapsulation material 214 is able to under-fill the spacing 410 between the semiconductor substrate 202 and the carrier substrate 210. The under-fill process may be carried out with molded under-filling or EMC or other materials combined to completely fill the spacing 410 in between.

In this embodiment, the encapsulation material 214 may be formed or deposited followed by a curing step within the temperature ranges as discussed earlier. After the encapsulation material 214 is cured, the encapsulation material 214 becomes partially rigid and forms an encapsulant or encapsulated structure. Furthermore, there is no need for the encapsulation material 214 to undergo a planarization process in this embodiment.

Next, FIG. 4F shows the semiconductor substrate 202 being removed from the carrier substrate 210 to form the semiconductor device 200, followed by removal of the sacrificial post 408 thereby creating a cavity 416 in its place. The removal of the carrier substrate 210 from the semiconductor substrate 202 can be achieved by removing or de-coupling the semiconductor substrate 202 from the carrier substrate 210 by separating the temporary adhesive layer 212. And like above, because of the nature of the material used in forming the sacrificial structure 408, the removal can be carried out by known etching techniques as discussed above. In this instance, because there is no planarization process being carried out in this embodiment, there is no risk associated with smearing or short circuiting.

In one embodiment, removal of the sacrificial structure 408 exposes the active region 206 of the semiconductor device 200 and allows electrical contact to be made. The direct electrical contact can be made by making electrical contacts to the active region 206 through the cavity 416.

FIG. 4G shows a cross-sectional view of a redistribution layer (RDL) structure 220 formed over the upper surface of the encapsulation material 214 after removal of the sacrificial structure 408 and formation of the cavity 416. As discussed above, at least a portion of the RDL structure 220 is in electrical contact with the active region 206 of the semiconductor device 200. Formation of the RDL structure 220 may be similar to that discussed above and will not be elaborated herein for sake of brevity.

In one embodiment, the RDL structure 220 associated with the current embodiment does not need a non-conformal metal structure 160 similar to that illustrated in FIG. 1A. A non-conformal metal structure includes a fill-up metal post or pillar (e.g., copper post or pillar 160).

In some embodiments, the currently disclosed eMFO packaging technology may use only one PID layer 140B, or two PID layer 140A, 140B, in the RDL structure 220, depending on cost, complexity and specification requirement. Regardless, the currently disclosed embodiments eliminate the need for a non-conformal metal structure, namely, a fill-up metal post or pillar using copper or other suitable metallic material.

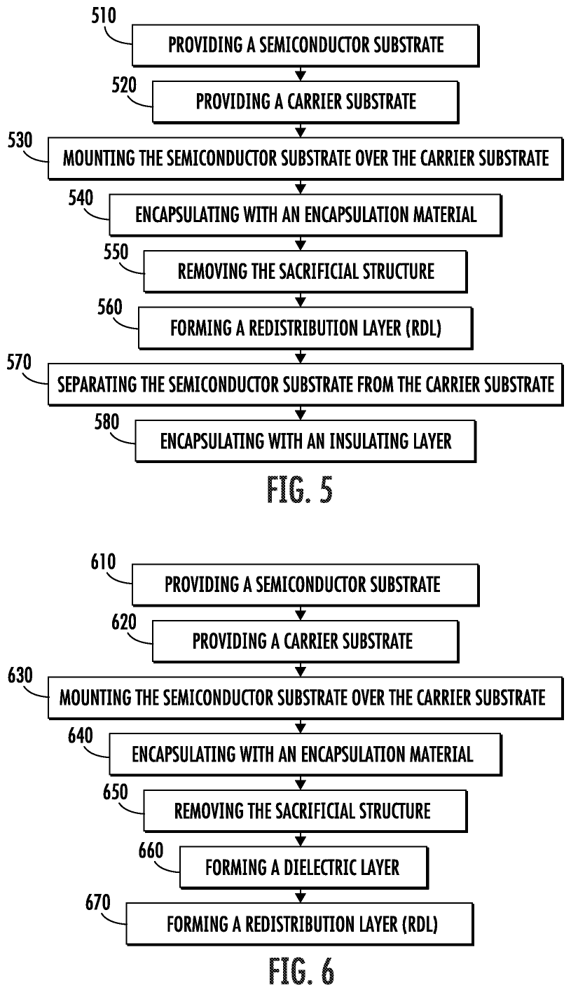

FIG. 5 is a process flow diagram showing an exemplary method for fabricating an eMFO package according to the present disclosure. In this embodiment, the method of manufacturing a semiconductor device starts with a step 510 of providing a semiconductor substrate having a semiconductor device with an active region and a sacrificial structure formed on the active region. In some embodiments, the providing step 510 includes forming the sacrificial structure from at least one of photo-sensitive polymers, non-photo-sensitive polymers, positive photoresists, negative photoresists, photo-imageable dielectric (PID) material, non-photo-imageable dielectric materials, benzocyclobutene (BCB), polybenzoxazoles (PBO), polyimide (PI), and heat-resistant thermoplastics.

In some embodiments, the next step 520 includes providing a carrier substrate having an adhesive layer. Although steps 510 and 520 are described in this order, it is understood that these steps may be reversed in other embodiments. In other words, in some embodiments, step 520 may be carried out first followed by step 510.

In one embodiment, the next step 530 includes mounting the semiconductor substrate over the carrier substrate, whereby the semiconductor substrate is in contact with the adhesive layer. Next step 540 includes encapsulating at least a portion of the semiconductor substrate and the sacrificial structure with an encapsulation material, whereby an upper surface of the encapsulation material is coplanar with an upper surface of the sacrificial structure. In some embodiments, the encapsulating step 540 includes planarizing the upper surface of the encapsulation material to be coplanar with the upper surface of the sacrificial structure via a planarizing process.

In some embodiments, the next step 550 includes removing the sacrificial structure exposing the active region of the semiconductor device. In some embodiments, the removing step 550 includes removing the sacrificial structure with at least one of dry etch and wet etch processing.

In some embodiments, the next step 560 includes forming a redistribution layer (RDL) structure over the semiconductor device, whereby at least a portion of the RDL structure is in electrical contact with the active region of the semiconductor device. In some embodiments, the forming step 560 includes forming the RDL structure without a non-conformal metal structure. In other embodiments, the non-conformal metal structure includes a fill-up metal post or pillar.

In some embodiments, the next step 570 includes removing the semiconductor substrate from the carrier substrate to form the semiconductor device. In other embodiments, the next step 580 includes encapsulating the semiconductor substrate and at least a portion of the encapsulation material with an insulating layer, whereby the insulating layer is coplanar with the semiconductor substrate and a lower surface of the encapsulation material.

FIG. 6 is a process flow diagram showing an exemplary method for fabricating an eMFO package according to the present disclosure. In this embodiment, the method of manufacturing a semiconductor device starts with a step 610 of providing a semiconductor substrate having a semiconductor device with an active region and a sacrificial structure formed on the active region. In some embodiments, the providing step 610 includes forming the sacrificial structure from at least one of photo-sensitive polymers, non-photo-sensitive polymers, positive photoresists, negative photoresists, photo-imageable dielectric (PID) material, non-photo-imageable dielectric materials, benzocyclobutene (BCB), polybenzoxazoles (PBO), polyimide (PI), and heat-resistant thermoplastics.

In some embodiments, the next step 620 includes providing a carrier substrate having an adhesive layer. Although steps 610 and 620 are described in this order, it is understood that these steps may be reversed in other embodiments. In other words, in some embodiments, step 620 may be carried out first followed by step 610.

In some embodiments, the next step 630 includes mounting the semiconductor substrate over the carrier substrate, whereby the semiconductor substrate is in contact with the adhesive layer.

In some embodiments, the next step 640 includes encapsulating at least a portion of the semiconductor substrate and the sacrificial structure with an encapsulation material, whereby an upper surface of the encapsulation material is coplanar with an upper surface of the sacrificial structure. In other embodiments, the next step 650 includes removing the sacrificial structure exposing the active region of the semiconductor device.

In some embodiments, the next step 660 includes forming a dielectric layer over at least a portion of the encapsulation material and the semiconductor device. In other embodiments, the next step 670 includes forming a redistribution layer (RDL) structure over the semiconductor device, whereby at least a portion of the RDL structure is in electrical contact with the active region of the semiconductor device. In some embodiments, the forming step 670 includes forming the RDL structure without a non-conformal metal structure. In other embodiments, the non-conformal metal structure includes a fill-up metal post or pillar.

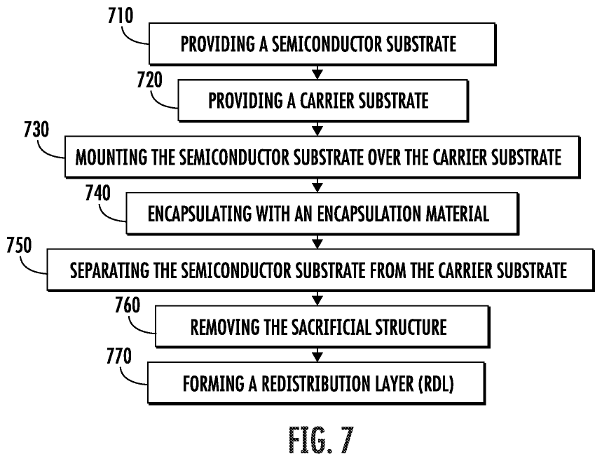

FIG. 7 is a process flow diagram showing an exemplary method for fabricating an eMFO package according to the present disclosure. In this embodiment, the method of manufacturing a semiconductor device starts with a step 710 of providing a semiconductor substrate having a semiconductor device with an active region.

In some embodiments, the next step 720 includes providing a carrier substrate having an adhesive layer and a sacrificial structure formed on a portion of the adhesive layer. In some embodiments, the providing step 720 includes forming the sacrificial structure from at least one of photo-sensitive polymers, non-photo-sensitive polymers, positive photoresists, negative photoresists, photo-imageable dielectric (PID) material, non-photo-imageable dielectric materials, benzocyclobutene (BCB), polybenzoxazoles (PBO), polyimide (PI), and heat-resistant thermoplastics.

Although steps 710 and 720 are described in this order, it is understood that these steps may be reversed in other embodiments. In other words, in some embodiments, step 720 may be carried out first followed by step 710.

In some embodiments, the next step 730 includes mounting the semiconductor substrate over the carrier substrate, whereby the active region is in contact with the sacrificial structure.

In some embodiments, the next step 740 includes encapsulating at least a portion of the semiconductor substrate and the sacrificial structure with an encapsulation material, whereby the encapsulation material under-fills spacing between the semiconductor substrate and the carrier substrate. In other embodiments, the next step 750 includes removing the semiconductor substrate from the carrier substrate.

In some embodiments, the next step 760 includes removing the sacrificial structure exposing the active region of the semiconductor device. In other embodiments, the next step 770 includes forming a redistribution layer (RDL) structure over the semiconductor device, wherein at least a portion of the RDL structure is in electrical contact with the active region of the semiconductor device. In some embodiments, the forming step 770 includes forming the RDL structure without a non-conformal metal structure. In other embodiments, the non-conformal metal structure includes a fill-up metal post or pillar.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A system comprising:
a semiconductor substrate having a semiconductor device with an active region and a sacrificial structure formed on the active region;
a carrier substrate having an adhesive layer, wherein the semiconductor substrate is disposed on the carrier substrate with the semiconductor substrate in contact with the adhesive layer;
an encapsulation material at least partially encapsulating the semiconductor substrate and a portion of the active region, wherein an upper surface of the encapsulation material is coplanar with an upper surface of the sacrificial structure; and
a redistribution layer (RDL) structure formed over the upper surface of the encapsulation material, after removal of the sacrificial structure, wherein at least a portion of the RDL structure is in electrical contact with the active region of the semiconductor device, the RDL structure without a non-conformal metal structure.

2. The system of claim 1, wherein the semiconductor substrate is removed from the carrier substrate to form the semiconductor device.

3. The system of claim 2, further comprising an insulating layer encapsulating the semiconductor substrate and at least a portion of the encapsulation material, wherein the insulating layer is coplanar with the semiconductor substrate and a lower surface of the encapsulation material.

4. The system of claim 1, wherein the sacrificial structure is formed from at least one of photo-sensitive polymers, non-photo-sensitive polymers, positive photoresists, negative photoresists, photo-imageable dielectric (PID) material, non-photo-imageable dielectric materials, benzocyclobutene (BCB), polybenzoxazoles (PBO), polyimide (PI), and heat-resistant thermoplastics.

5. The system of claim 1, wherein the RDL structure includes only a single dielectric layer.

6. The system of claim 1, wherein the non-conformal metal structure includes a fill-up metal post or pillar.

7. A method comprising:
(a) providing a semiconductor substrate having a semiconductor device with an active region and a sacrificial structure formed on the active region;
(b) providing a carrier substrate having an adhesive layer;
(c) mounting the semiconductor substrate over the carrier substrate, wherein the semiconductor substrate is in contact with the adhesive layer;
(d) encapsulating at least a portion of the semiconductor substrate and the sacrificial structure with an encapsulation material, wherein an upper surface of the encapsulation material is coplanar with an upper surface of the sacrificial structure;
(e) removing the sacrificial structure exposing the active region of the semiconductor device; and
(f) forming a redistribution layer (RDL) structure over the semiconductor device, wherein at least a portion of the RDL structure is in electrical contact with the active region of the semiconductor device.

8. The method of claim 7, further comprising:
(g) removing the semiconductor substrate from the carrier substrate to form the semiconductor device.

9. The method of claim 8, further comprising:
(h) encapsulating the semiconductor substrate and at least a portion of the encapsulation material with an insulating layer, wherein the insulating layer is coplanar with the semiconductor substrate and a lower surface of the encapsulation material.

10. The method of claim 7, wherein the providing step (a) includes forming the sacrificial structure from at least one of photo-sensitive polymers, non-photo-sensitive polymers, positive photoresists, negative photoresists, photo-imageable dielectric (PID) material, non-photo-imageable dielectric materials, benzocyclobutene (BCB), polybenzoxazoles (PBO), polyimide (PI), and heat-resistant thermoplastics.

11. The method of claim 7, wherein the encapsulating step (d) includes planarizing the upper surface of the encapsulation material to be coplanar with the upper surface of the sacrificial structure via a planarizing process.

12. The method of claim 7, wherein the removing step (e) includes removing the sacrificial structure with at least one of dry etch and wet etch processing.

13. The method of claim 7, wherein the forming step (f) includes forming the RDL structure without a non-conformal metal structure.

14. The method of claim 13, wherein the non-conformal metal structure includes a fill-up metal post or pillar.

15. A method comprising:
(a) providing a semiconductor substrate having a semiconductor device with an active region and a sacrificial structure formed on the active region;
(b) providing a carrier substrate having an adhesive layer;
(c) mounting the semiconductor substrate over the carrier substrate, wherein the semiconductor substrate is in contact with the adhesive layer;
(d) encapsulating at least a portion of the semiconductor substrate and the sacrificial structure with an encapsulation material, wherein an upper surface of the encapsulation material is coplanar with an upper surface of the sacrificial structure;
(e) removing the sacrificial structure exposing the active region of the semiconductor device;
(f) forming a redistribution layer (RDL) structure over the semiconductor device, wherein at least a portion of the RDL structure is in electrical contact with the active region of the semiconductor device;
(g) removing the semiconductor substrate from the carrier substrate to form the semiconductor device; and
(h) encapsulating the semiconductor substrate and at least a portion of the encapsulation material with an insulating layer, wherein the insulating layer is coplanar with the semiconductor substrate and a lower surface of the encapsulation material.

16. The method of claim 15, wherein the providing step (a) includes forming the sacrificial structure from at least one of photo-sensitive polymers, non-photo-sensitive polymers, positive photoresists, negative photoresists, photo-imageable dielectric (PID) material, non-photo-imageable dielectric materials, benzocyclobutene (BCB), polybenzoxazoles (PBO), polyimide (PI), and heat-resistant thermoplastics.

17. The method of claim 15, wherein the encapsulating step (d) includes planarizing the surface of the encapsulation material to be coplanar with the upper surface of the sacrificial structure via a planarizing process.

18. The method of claim 15, wherein the removing step (e) includes removing the sacrificial structure with at least one of dry etch and wet etch processing.

19. The method of claim 15, wherein the forming step (f) includes forming the RDL structure without a non-conformal metal structure.

20. The method of claim 19, wherein the non-conformal metal structure includes a fill-up metal post or pillar.
